(19) United States
(12) Patent Application Publication
(10) Pub. No.: US 2026/0101466 A1
(43) Pub. Date: Apr. 9, 2026

(54) VEHICLES AND ELECTRONIC ASSEMBLIES HAVING COOLING ASSEMBLIES WITH CONVERGING AND DIVERGING CHANNELS

(71) Applicants: Toyota Motor Engineering & Manufacturing North America, Inc., Plano, TX (US); Trinity College, Dublin (IE)

(72) Inventors: Georoid Farrell, Dublin (IE); Rajesh Nimmagadda, Dublin (IE); Tim Persoons, Dublin (IE); Shailesh N. Joshi, Ann Arbor, MI (US); Danny J. Lohan, Northville, MI (US); Ercan Mehmet Dede, Ann Arbor, MI (US)

(73) Assignees: Toyota Motor Engineering & Manufacturing North America, Inc., Plano, TX (US); Trinity College, Dublin (IE)

(21) Appl. No.: 18/905,758

(22) Filed: Oct. 3, 2024

(51) Int. Cl. H05K 7/20

(52) U.S. Cl. CPC H05K 7/20127; H05K 7/209

(57) ABSTRACT

In one embodiment, a cooling assembly including a plate includes an array of internal fins, a surface, and a plurality of openings, wherein the array of internal fins defines an array of internal channels, and a plurality of angled fins extending from the plate. The plurality of angled fins define a plurality of channels includes alternating converging channels and diverging channels. The array of internal channels is fluidly coupled to the plurality of channels defined by the plurality of angled fins.

### BACKGROUND

Heat generating components, such as power electronic devices, may require to removal of heat flux so that they operate below their maximum operating temperature. Cooling devices such as heat sinks may be used to transfer heat flux from a heat generating component to the ambient air. Convection may be used to force airflow through an array of fins of the heat sink. The array of fins increases the surface area that the airflow is exposed to, thereby increasing the transfer of heat to the airflow.

Vehicles, such as electric vehicles like automobiles, trucks and aircraft, may include inverter circuits having power electronic devices that generated significant heat fluxes that should be removed. Movement of the vehicle through the environment creates a natural airflow around the vehicle as it travels. However, including fins of a heat sink on the body of the vehicle will increase drag on the vehicle, thereby lowering efficiency of the vehicle.

Accordingly, alternative cooling assemblies for cooling heat generating components may be desired.

### BRIEF SUMMARY

In one embodiment, a cooling assembly including a plate includes an array of internal fins, a surface, and a plurality of openings, wherein the array of internal fins defines an array of internal channels, and a plurality of angled fins extending from the plate. The plurality of angled fins define a plurality of channels includes alternating converging channels and diverging channels. The array of internal channels is fluidly coupled to the plurality of channels defined by the plurality of angled fins.

In another embodiment, an electronic assembly includes a plate having an array of internal fins, a first surface, a second surface, and a plurality of openings. The array of internal fins defines an array of internal channels, and a plurality of angled fins extending from a first surface of the plate. The plurality of angled fins define a plurality of channels that includes alternating converging channels and diverging channels, wherein the array of internal channels is fluidly coupled to the plurality of channels defined by the plurality of angled fins. The electronic assembly further includes one or more electronic devices coupled to a second surface of the plate.

In another embodiment, a vehicle includes a body. The vehicle also includes an electronic assembly coupled to the body, the electronic assembly including a plate having an array of internal fins, a first surface, a second surface, and a plurality of openings. The array of internal fins defines an array of internal channels and a plurality of angled fins extending from a first surface of the plate. The plurality of angled fins define a plurality of channels that includes alternating converging channels and diverging channels, wherein the array of internal channels is fluidly coupled to the plurality of channels defined by the plurality of angled fins. The vehicle further includes one or more electronic devices coupled to a second surface of the plate.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1A illustrates an isometric view of an example cooling assembly according to one or more embodiments described and illustrated herein.

FIG. 1B illustrates a top view of an example cooling assembly according to one or more embodiments described and illustrated herein.

FIG. 1C illustrates a side view of a cooling assembly according to one or more embodiments described and illustrated herein.

FIG. 2 illustrates another top view of an example cooling assembly according to one or more embodiments described and illustrated herein.

FIG. 3 illustrates a partial isometric view of a cooling assembly according to one or more embodiments described and illustrated herein.

FIG. 4 illustrates results of a simulation showing high and low pressures of an example cooling assembly according to one or more embodiments described and illustrated herein.

FIG. 5 illustrates a top view of a plate of an example cooling assembly having a chevron pattern of internal fins according to one or more embodiments described and illustrated herein.

FIG. 6 illustrates an example vehicle having a plurality of cooling assemblies according to one or more embodiments described and illustrated herein.

### DETAILED DESCRIPTION

Embodiments of the present disclosure reduce pressure drop and drag caused by heat sinks to cool heat generating components by providing angled fins that are arranged generally in the direction of airflow, while re-routing a fraction of air below a plate surface to receive additional heat energy from internal fins. The cooling assemblies cooling assemblies described herein have a low pressure drop by utilizing angled fins to produce a pressure difference between alternating converging channels and diverging channels. More particularly, ambient air approaches the angled fins and is allowed to flow through the converging and diverging channels. The converging channels create regions of high pressure, while the diverging channels create regions of low air pressure. These regions of high and low air pressure are fluidly coupled to an internal heat sink comprising an array of internal fins that define an array of internal channels. The pressure difference is leveraged to pump a fraction of air into the internal channels. This re-routed air travels within the internal channels from the converging channels and then exits at a diverging channel. The re-routed air is brought in close proximity to the heat generating components that are to be cooled such that the re-routed air is warmed up, thereby extracting heat from the internal fins. The warmed re-routed air then exits the internal heat sink on the diverging channel sides where it joins the freestream of air that flows through the diverging channel and exits at the backside of the cooling assembly.

When embedded in the surface of a body (e.g., a vehicle) and exposed to airflow (either from a fan or from movement of the body itself), the cooling assemblies of the present disclosure utilize a novel, streamlined external manifold that directs airflow to the internal heat sink that is “hidden” from the external flow, and removes the need to the entire heat sink to be directly exposed to the external airflow, which would increase drag on the system. Various embodiments of cooling assemblies are described in detail below.

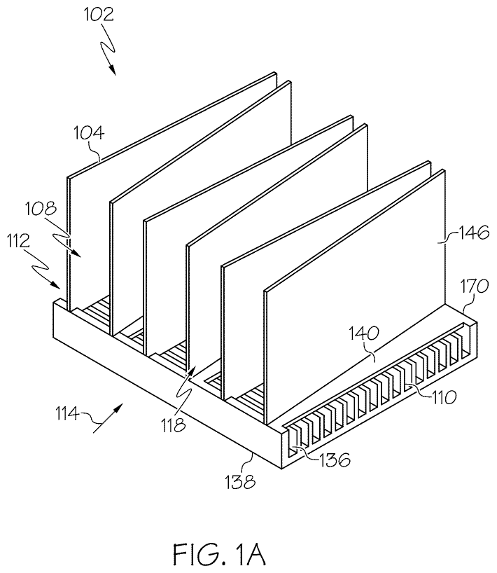

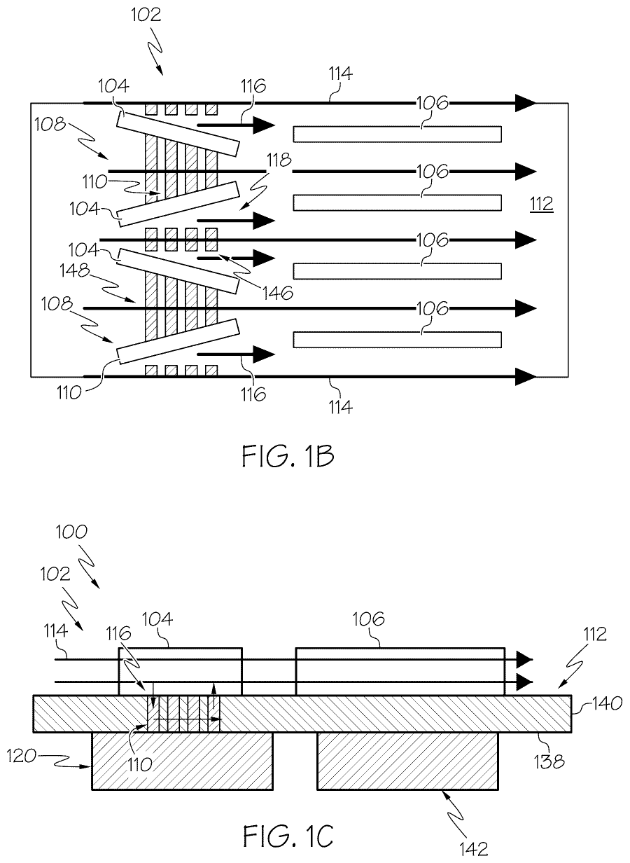

Referring now to FIG. 1A, an example cooling assembly 102 is illustrated in an isometric view. The cooling assembly 102 includes a plate 112 having an array of internal fins 110. The internal fins 110 may be parallel to one another and extend along one axis. In other embodiments, the internal fins 110 may not run parallel to one another. The array of internal fins 110 define an array of internal channels 162 through which re-routed air 116 travels, as described in more detail below.

The plate 112 has a heat receiving surface 138 and a cooling surface 140. The array of internal fins 110 extend between the heat receiving surface 138 and the cooling surface 140. Thus, the array of internal channels 136 is disposed between the heat receiving surface 138 and the cooling surface 140. The height of the array of internal fins 110, and therefore the distance between the heat receiving surface 138 and the cooling surface 140, is not limited by this disclosure and may depend on the particular application.

The plate 112 may be fabricated from any suitable thermally conductive material, such as, without limitation, aluminum and copper. The heat receiving surface 138 is configured to be coupled to one or more heat generating components, such as first heat generating components 120 and second heat generating components 142 as shown in FIG. 1C. It should be understood that one or more heat generating components may be used. The heat generating components are thermally coupled to the heat receiving surface 138 by any suitable means, such as, without limitation, by thermal paste, soldering, sintering, or brazing.

The heat generating component(s) may be any component in need of cooling. As a non-limiting example, the heat generating components may be power electronic devices, such as power switching devices used in inverter circuits for use in electric vehicles. The power electronic devices may include, but are not limited to, insulated-gate bi-polar transistors (IGBTs), metal-oxide-semiconductor field-effect transistors (MOSFETs), power transistors, and power diodes.

The cooling surface 140 of the plate 112 is opposite from the heat receiving surface 138 and is operable to receive air 114 that is generated by one or more fans or propellers (not shown) or by movement of the cooling assembly 102 through the environment.

The cooling assembly 102 further includes a plurality of angled fins 104 that extends from the cooling surface 140. The angled fins 104 are angled such that they are non-orthogonal with respect to an exit edge 144 of the plate. The angled fins 104 define alternating converging channels 108 and diverging channels 118. Thus, a converging channel 108 is adjacent to a diverging channel 118. In the converging channels 108 the distance between the two angled fins 104 decrease in a direction of the air 114. In the diverging channels 118 the distance between the two angled fins 104 increases in a direction of the air 114. An individual angled fin may define both a converging channel 108 and a diverging channel 118. The angled fins 104 are made of a thermally conductive material, and may have any height. As non-limiting examples, the angled fins 104 may be made of aluminum or copper.

Referring now to FIG. 1B and FIG. 1C, the air 114 flows through both the converging channels 108 and the diverging channels 118. The flow of air 114 may be generated by fans, propellers or other devices. The flow of air 114 may also generated by the cooling assembly 102 moving through the environment. As a non-limiting example, the cooling assembly 102 may be attached to a component of a moving vehicle, such as a car, a plane, or a vertical take-off and landing vehicle (VTOL). The air 114 moves through the converging channels 108 and diverging channels 118 and then past the cooling assembly 102.

Gaps between the adjacent angled fins 104 allow the air 114 to flow within both the converging channels 108 and the diverging channels 118. Because there are gaps between the adjacent angled fins 104, air 114 is not forced into the internal channels 136 by blocking the exit of the converging channels 108. Rather, air is able to flow through the converging channels 108 and exit on the other side of the cooling assembly 102. However, the approaching air experiences a higher flow resistance in the converging channels 108 than the diverging channels 118 due to the converging shape. This causes some of the approaching air to bypass the converging channels 108 and instead flow within the diverging channels 118 that have a lower flow resistance. This redistribution of airflow causes a locally lower flow rate and higher static pressure in the converging channels 108, and a locally higher flow rate and lower static pressure in the diverging channels 118. In total, this causes a significant pressure difference between adjacent converging channels 108 and diverging channels 118.

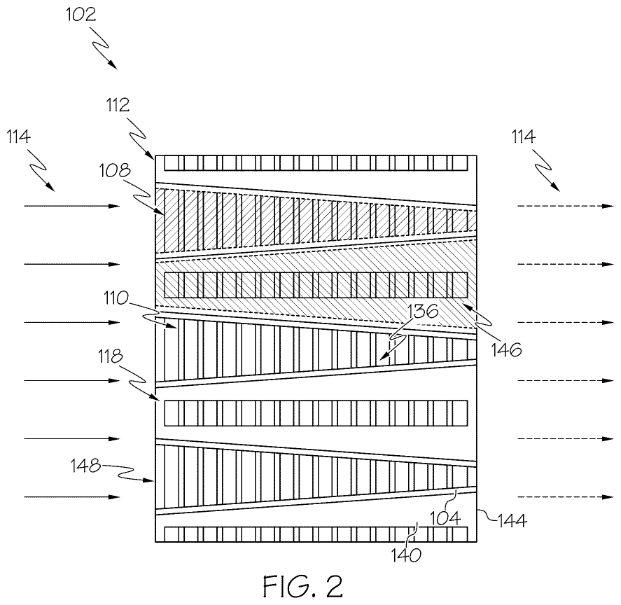

The cooling surface 140 of the plate 112 exposes the internal channels 136 by way of openings within the converging channels 108 and the diverging channels 118. As shown in FIG. 1B and FIG. 2, the internal channels 136 are exposed by full openings 148 within the converging channels 108, and are partially exposed by partial openings 146 within the diverging channels 118. Thus, the internal channels 136 are partially blocked by the cooling surface 140 of the plate 112. In the illustrated embodiment the partial openings 146 arc rectangular in shape but embodiments are not limited thereto. The full openings 148 within the diverging channels 118 encourage air 114 to enter the internal channels 136 of the plate 112.

The converging channels 108 and the diverging channels 118 act primarily as a manifold, and use the pressure difference created between the converging channels 108 and the diverging channels 118 to “pump” a fraction of the air 114 into the internal channels 136 within the plate 112. The mechanism used to create the pressure difference to pump air into the internal heat sink is based on Bernoulli's Principle, which states that increasing a fluid's velocity decreases its static pressure, while decreasing its velocity has the opposite effect. Referring to FIG. 1B, a fraction of the incoming air passes through the diverging channels 118 and a fraction of the incoming air 114 passes through the converging channels 108. Due to the pressure differential, a fraction of the air 114 passing into the internal channels 136 of the plate 112. The converging channel 108 creates a higher flow resistance than the diverging channel 118. This slows the air in the converging channel 108 and causes some air to bypass the converging channel 108 and enter the diverging channel 118 instead. This redistribution of air at the inlet of the manifold reduces the flow velocity of air in the converging channel 108, and increases the flow of velocity in the diverging channel 118. This has the effect of increasing the static pressure in the converging channel 108 region, while lowing the static pressure in the diverging channel 118 region. Thus, a significant pressure differential between the converging channels 108 and the diverging channels 118 is created that can be exploited to pump some fraction of air through the internal channels 136.

FIG. 1C illustrates how re-routed air 116 within a converging channel 108 is directed downward into the internal channels 136 and past the internal fins 110, where it receive heat flux from one or more first heat generating components 120 (e.g., power electronic devices). The re-routed air 116 then flows upward into a diverging channel 118 and may exit the cooling assembly 102.

The example cooling assembly 102, which is a component of an electronic assembly 100, includes additional straight fins 106 that are downstream from the angled fins 104. The straight fins 106 may be included to cool second heat generating components 142, which may be additional heat generating components that do not require as much heat flux removal as the first heat generating components 120. For example, the second heat generating components 142 may be gate drive electronics for controlling the power electronic devices that define the first heat generating components 120. It should be understood that in some embodiments no additional straight fins 106 are provided.

It is noted that a bypass of air 114 around the manifold defined by the angled fins 104 cannot be avoided. Therefore, the pressure drop across the cooling assembly 102 should be minimized to reduce the bypass. In embodiments of the present disclosure, the pressure drop across the cooling assembly 102 is within a range of 100 Pa to 200 Pa, including endpoints. However, the shape and configuration of the manifold defined by the cooling assembly 102 may provide different pressure drops according to the end application.

It is further noted that because the interior heat sink defined by the internal fins 110 of the plate are beneath the cooling surface 140, the cooling assembly 102 has low-drag characteristics as compared with conventional heat sinks, which is beneficial in aircraft applications.

FIG. 2 is an top view of the example cooling assembly 102 of FIG. 1A. Cool incoming air 114 is routed through both the converging channels 108 and diverging channels 118, as well as into and out of the internal channels 136. Warmed air then exits the converging channels 108 and diverging channels 118. As described above, the internal channels 136 are fully exposed within the converging channels 108 to encourage pumping of air 114 into the internal channels 136. The internal channels 136 are partially exposed within the diverging channels 118 by partial openings 146 such that the cooling surface 140 of the plate partially covers the internal channels 136.

Each angled fin 104 is angled such that it is non-orthogonal with respect to an edge of the plate 112, such as exit edge 144. The angled fins 104 define the converging channels 108 and the diverging channels 118.

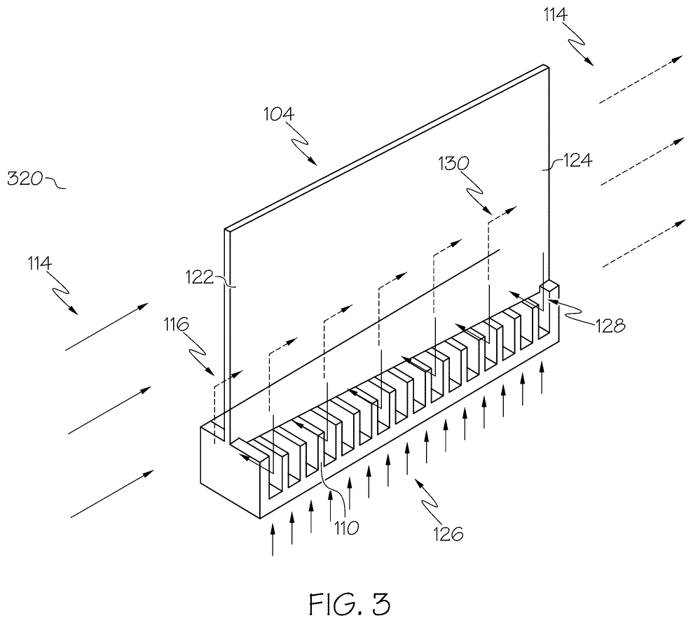

FIG. 3 is a partial isometric view of the cooling assembly 102 that illustrates the path that the re-routed air 116 takes when it is re-routed into the internal channels 136. Incoming air 114 passes into a converging channel 108 whereby it flows by a converging side 124 of an angled fin 104. The pressure differential between the converging channel 108 and the adjacent diverging channels 118 causes cool re-routed air 128 to flow downward into the internal channels 136 defined by the internal fins 110. The cool re-routed air 128 receives heat flux 126 from the one or more heat generating components as it flows within the internal channels 136. The re-routed air 116 passes under the angled fin 104 from the converging side 124 to the diverging side 122, where it becomes warm re-routed air 130. The warm re-routed air 130 then flows upward out of the partial opening 146 within the diverging channel 118 on the diverging side 122 of the angled fin 104 where it then exits the cooling assembly 102 as warm air 114.

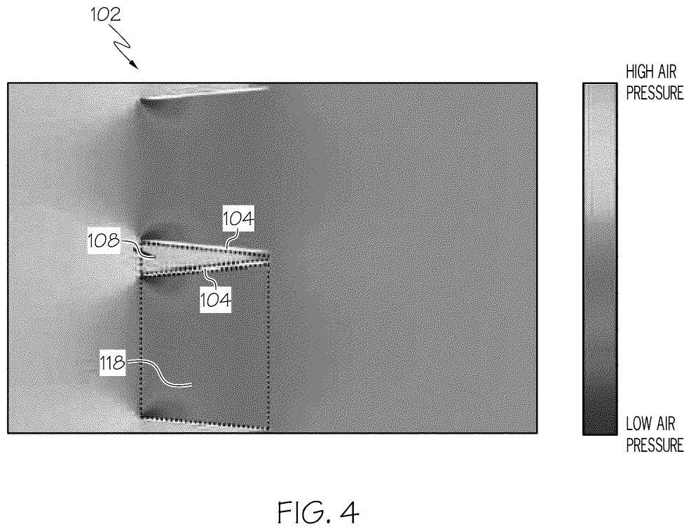

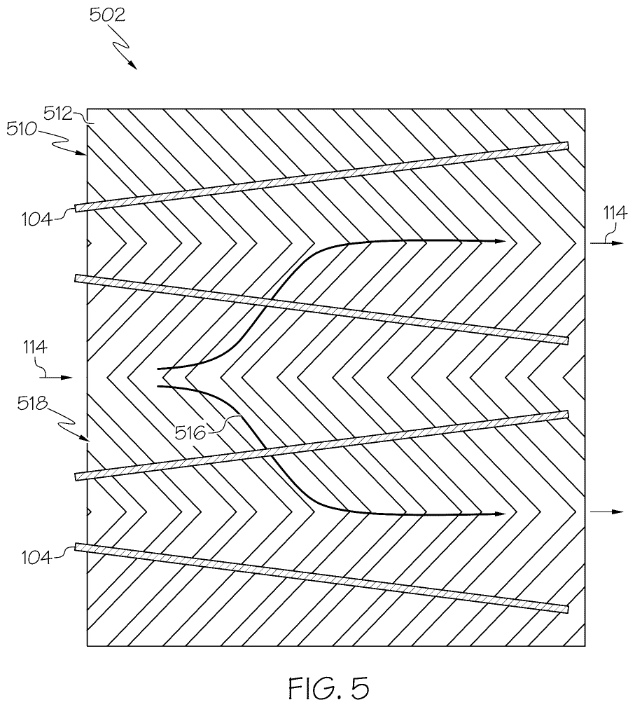

FIG. 4 graphically illustrates a simulation of angled fins 104 that form converging channels 108 and diverging channels 118. The converging channels 108 form high pressure areas while the diverging channels 118 form low pressure areas wherein the high pressure areas have a greater air pressure than the low pressure areas. By varying the width of the converging channels 108 and the diverging channels 118, pressure differentials between 80 Pa and 180 Pa can be achieved (measured between the centerlines of the converging channels 108 and the diverging channels 118.

The internal fins 110 may take on any size, shape and configuration. Although FIGS. 1A-3 show the internal fins 110 as being parallel to the exit edge 144 of the plate 112, embodiments are not limited thereto. Referring to now to FIG. 5, a plate 512 of another example cooling assembly 502 is illustrated. The plate 512 of this embodiment has internal fins 510 that are non-parallel to the edges of the plate 512. Particularly, the internal fins 510 are angled such that they define a chevron pattern. The internal fins 510 define internal channels 518 that also arranged in a chevron pattern. The angled internal channels 518 reduces the angle that the re-routed air 116 must turn when traveling along the interior of the plate 512, thereby reducing flow resistance through the internal channels 518 which in turn reduces the pressure drop across the cooling assembly 502.

Other internal fin configurations may also be provided. For example, the internal fins may be pin fins. The internal fins of the present disclosure may also be porous, which increases the surface area through which the re-routed air travels through the internal channels.

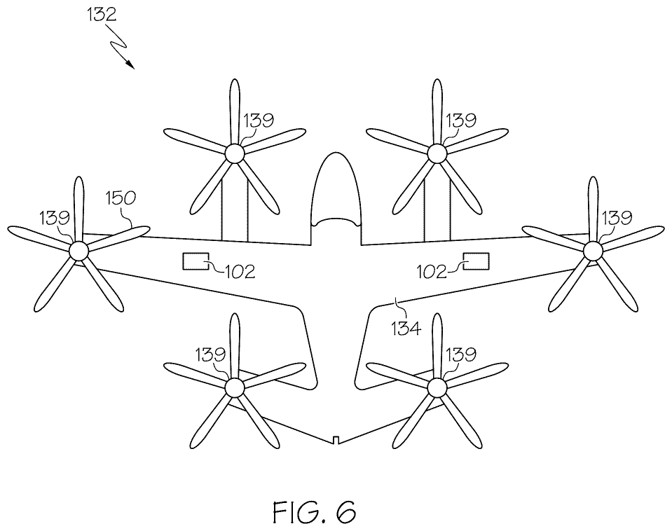

The cooling assemblies described herein may be incorporated into any device having heat generating components that should be cooled. Such devices include vehicles, such as the vehicle 132 illustrated in FIG. 6. The vehicle 132 of FIG. 6 is configured as an electric vertical take-off and landing aircraft (eVTOL). However, it should be understood that the vehicle 132 may take on other configurations, such as an airplane, an automobile, a truck, a train, a monorail, and the like. Any device where air flows by it may be configured to have the cooling assemblies 102 as described herein. The vehicle 132 may have one or more cooling assemblies 102. As a non-limiting example, the cooling surface 140 may be flush with the surface of the body 134 the vehicle 132, such as the wing of the vehicle 132.

In the present example, airflow generated by the propellers 150 of the vehicle 132, as well as movement of the vehicle 132 through the atmosphere, passes into the manifold of the cooling assemblies 102 defined by the angled fins 104. Because the angled fins 104 are generally arranged in the direction of the air 114, they produce a relatively low pressure drop across the cooling assemblies 102. The internal fins 110 are below the surface of the body 134, and therefore only minimally contribute to drag on the vehicle 132.

In some embodiments, the cooling assemblies 102 are coupled to the vehicle 132 at one or more electric aircraft motors 139, such as at the nacelle of the electric aircraft motor 139 (e.g., the cowling component) where the power electronics are mounted internally and in close proximity to the electric machine of the electric aircraft motor 139.

It should now be understood that embodiments of the present disclosure are directed to cooling assemblies that cool heat generating components having a low pressure drop by utilizing angled fins to produce a pressure difference between alternating converging channels and diverging channels. More particularly, ambient air approaches the angled fins and is allowed to flow through the converging and diverging channels. The converging channels create regions of high pressure, while the diverging channels create regions of low air pressure. These regions of high and low air pressure are fluidly coupled to an internal heat sink comprising an array of internal fins that define an array of internal channels. The pressure difference is leveraged to pump a fraction of air into the internal channels. This re-routed air travels within the internal channels from the converging channels and then exits at a diverging channel. The re-routed air is brought in close proximity to the heat generating components that are cooled such that the re-routed air is warmed up, thereby extracting heat from the internal fins. The warmed re-routed air then exits the internal heat sink on the diverging channel sides where it joins the freestream of air that flows through the diverging channel and exits at the backside of the cooling assembly.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

It will be apparent to those skilled in the art that various modifications and variations can be made to the embodiments described herein without departing from the scope of the claimed subject matter. Thus, it is intended that the specification cover the modifications and variations of the various embodiments described herein provided such modification and variations come within the scope of the appended claims and their equivalents.

What is claimed is:

1. A cooling assembly comprising:
a plate comprising an array of internal fins, a surface, and a plurality of openings, wherein the array of internal fins defines an array of internal channels; and
a plurality of angled fins extending from the plate, wherein the plurality of angled fins define a plurality of channels comprising alternating converging channels and diverging channels, wherein the array of internal channels is fluidly coupled to the plurality of channels defined by the plurality of angled fins.

2. The cooling assembly of claim 1, wherein each angled fin of the plurality of angled fins is non-orthogonal with respect to an edge of the plate.

3. The cooling assembly of claim 1, wherein the surface is present on the plate within the diverging channels and the surface defines an opening to expose the array of internal channels within the diverging channels.

4. The cooling assembly of claim 3, wherein the opening is a rectangular opening along a length of the plate.

5. The cooling assembly of claim 1, wherein:
the plurality of angled fins are operable to receive an airflow in an airflow direction;
the airflow and the plurality of angled fins create a high pressure within the converging channels and a low pressure within the diverging channels; and
the high pressure is greater than the low pressure.

6. The cooling assembly of claim 5, wherein the high pressure and the low pressure causes air to flow from the converging channels, into the array of internal channels, and into the diverging channels.

7. The cooling assembly of claim 1, wherein the array of internal fins define a chevron pattern.

8. An electronic assembly comprising:
a plate comprising an array of internal fins, a first surface, a second surface, and a plurality of openings, wherein the array of internal fins defines an array of internal channels;
a plurality of angled fins extending from the first surface of the plate, wherein the plurality of angled fins define a plurality of channels comprising alternating converging channels and diverging channels, wherein the array of internal channels is fluidly coupled to the plurality of channels defined by the plurality of angled fins; and
one or more electronic devices coupled to the second surface of the plate.

9. The electronic assembly of claim 8, wherein each angled fin of the plurality of angled fins is non-orthogonal with respect to an edge of the plate.

10. The electronic assembly of claim 8, wherein the first surface is present on the plate within the diverging channels and the first surface defines an opening to expose the array of internal channels within the diverging channels.

11. The electronic assembly of claim 10, wherein the opening is a rectangular opening along a length of the plate.

12. The electronic assembly of claim 8, wherein:
the plurality of angled fins are operable to receive an airflow in an airflow direction;
the airflow and the plurality of angled fins create a high pressure within the converging channels and a low pressure within the diverging channels; and
the high pressure is greater than the low pressure.

13. The electronic assembly of claim 12, wherein the high pressure and the low pressure causes air to flow from the converging channels, into the array of internal channels, and into the diverging channels.

14. The electronic assembly of claim 8, wherein the array of internal fins define a chevron pattern.

15. A vehicle comprising:
a body; and
an electronic assembly coupled to the body, the electronic assembly comprising:
a plate comprising an array of internal fins, a first surface, a second surface, and a plurality of openings, wherein the array of internal fins defines an array of internal channels;
a plurality of angled fins extending from the first surface of the plate, wherein the plurality of angled fins define a plurality of channels comprising alternating converging channels and diverging channels, wherein the array of internal channels is fluidly coupled to the plurality of channels defined by the plurality of angled fins; and
one or more electronic devices coupled to the second surface of the plate.

16. The vehicle of claim 15, wherein the vehicle is an aircraft comprising an electric motor, and the electronic assembly is coupled to the vehicle at the electric motor.

17. The vehicle of claim 15, wherein each angled fin of the plurality of angled fins is non-orthogonal with respect to an edge of the plate.

18. The vehicle of claim 15, wherein the first surface is present on the plate within the diverging channels and the first surface defines an opening to expose the array of internal channels within the diverging channels.

19. The vehicle of claim 18, wherein the opening is a rectangular opening along a length of the plate.

20. The vehicle of claim 15, wherein:
the plurality of angled fins are operable to receive an airflow in an airflow direction;
the airflow and the plurality of angled fins create a high pressure within the converging channels and a low pressure within the diverging channels; and
the high pressure is greater than the low pressure.
